(19) United States
(12) Patent Application Publication
(10) Pub. No.: US 2024/0018690 A1
(43) Pub. Date: Jan. 18, 2024

(54) METHOD AND APPARATUS FOR PROCESSING A SINGLE CRYSTAL BLANK

(71) Applicant: DISCO CORPORATION, Tokyo (JP)

(72) Inventor: Manuel KRUSE, Munich (DE)

(21) Appl. No.: 18/348,533

(22) Filed: Jul. 7, 2023

(30) Foreign Application Priority Data
Jul. 12, 2022 (DE) 10 2022 207 109.3

(51) Int. Cl. C30B 33/08

(52) U.S. Cl. CPC C30B 33/08

(57) ABSTRACT

The disclosed method is for processing a single crystal. The single crystal has a first end, a second end and a longitudinal axis between said first end and said second end. The single crystal comprises a seed crystal, wherein the seed crystal extends at least partially along the longitudinal axis. The method comprises a peripheral surface grinding step of grinding a peripheral surface of the single crystal at least partially along the longitudinal axis. The peripheral surface of the single crystal is ground up to a first distance to the longitudinal axis at least partially along a portion of the longitudinal axis excluding the seed crystal, wherein the first distance is preferably less than an extension of the seed crystal to the longitudinal axis.

### TECHNICAL FIELD

The present invention relates to a method for processing a single crystal blank including a seed crystal and a grown single crystal, wherein the single crystal blank is processed for forming an ingot or a single wafer. The present invention also relates to an apparatus for processing a single crystal blank by applying the method.

### BACKGROUND

Single crystals for producing semiconductor devices or optical devices are generally grown from seed crystals to form single crystal blanks. Although these single crystal blanks are grown to have a shape that approximately corresponds to a desired shape and size of an ingot or a wafer, the blanks generally require processing to closely adopt this shape with a manufacturing quality that allows further processing.

The process of growing single crystals starts based on seed crystals. These seed crystals are of a particularly high quality to provide a single crystal grown starting from this seed crystal with the characteristics needed for subsequently manufacturing above-noted devices. More specifically, a seed crystal needs to have a uniform structure since any defects in a seed crystal may replicate during growth of the single crystal.

Due to the nature of the growth process, a single crystal grown from a seed crystal is integral with the single crystal blank and is processed accordingly. As a result, such a seed crystal is not reused but is lost after the growth process has ended.

The high quality needed for growing single crystals as well as the one-time use of these seed crystals cause significant costs during production of the single crystal blanks. This is particularly case of only a few wafers or even a single wafer is to be produced from such a seed crystal.

Further, it has been observed that different seed crystals deliver different results in terms of quality of the single crystals originating from these seed crystals. However, this observation takes place after having grown a seed crystal into a single crystal blank. In this respect, the loss of the seed crystals that achieve the desired growth results is particularly undesirable.

Further, it is to be noted that the focus of the semiconductor industry shifted in recent years from silicon to other materials as alternatives or due to new technologies. One example of such a material is silicon carbide (SiC), which is particularly apt for power devices (e.g. SBD (Schottky barrier diode), MOSFET (metal oxide semiconductor field effect transistor), IGBT (insulated gate bipolar transistor), etc.) that are subject to an increasing demand. However, this material is also more expensive in production. Accordingly, this is also the case for the seed crystals used to grow single crystal blanks of SiC.

### SUMMARY

In view of the above-described circumstances, there remains an interest in driving manufacturing costs of the single crystal blanks for producing ingots and wafers down.

Having this underlying situation in mind, the present disclosure provides a method for processing a single crystal blank, wherein the single crystal blank has a first end, a second end and a longitudinal axis extending between the first end and the second end. The single crystal blank includes a seed crystal, wherein the seed crystal extends at least partially along the longitudinal axis. The method comprises a peripheral surface grinding step of grinding a peripheral surface of the single crystal blank at least partially along the longitudinal axis. The peripheral surface of the single crystal blank is ground up to a first distance to the longitudinal axis at least partially along a portion of the longitudinal axis excluding the seed crystal, wherein the first distance is preferably less than an extension of the seed crystal to the longitudinal axis.

The single crystal blank includes the seed crystal and the single crystal that has been grown starting from the seed crystal. In the following it is generally referred to the seed crystal of the single crystal blank as the seed crystal and to the single crystal grown starting from the seed crystal as grown single crystal or single crystal. When referring to a distance, it is generally referred to the shortest distance between two geometrical entities.

In respect to the method employed for growing the single crystal in order to produce the single crystal blank is not particularly limited. However, the cost benefits of the disclosed method are particularly advantageous for seed crystals that have approximately the same shape and size in cross-section as the single crystal grown on a surface of the seed crystal. In such a method, the growth of the single crystal particularly starts from a face side of the seed crystal. Accordingly, the cross-section of the seed crystal generally corresponds to the cross-section of the single crystal grown on top of the seed crystal.

The face side in the present context is defined as a surface, which faces in the longitudinal direction or in the direction of primary growth of the single crystal which is grown on the seed crystal. For example, the single crystal blank having a first end, a second end, a longitudinal axis extending between the first and second end, and a peripheral surface surrounding the longitudinal axis, comprises a face side which faces in the longitudinal direction and, in particular, in the growing direction of the single crystal.

Further, the seed crystal and the resulting single crystal grown on top of the seed crystal generally correspond in shape to a wafer or an ingot to be produced therefrom. However, the cross-sections of both the seed crystal and the grown single crystal are preferably larger than the cross-section of the wafer or ingot to be produced. This larger size is particularly chosen in consideration of irregularities in shape and size of the single crystal due to the nature of the growth process. In other words, the larger size in cross-section of the single crystal blank allows for machining, in particular grinding, of at least (preferably only) the grown single crystal to a predetermined shape and size while removing growth irregularities.

Nonetheless, the single crystal may be grown to have an extension in a cross-section, i.e. perpendicular to the longitudinal axis, that is equal to or slightly exceeds the dimension of the seed crystal's cross-section due to growth irregularities.

Preferably, the seed crystal basically forms one end of the seed crystal blank during and after growth. Further, the single crystal on top of the seed crystal is preferably grown to approximately have a cylindrical shape, wherein the cross-sectional profile and size of the seed crystal generally defines the cross-sectional profile of the grown single crystal of the single crystal blank (e.g. the tip portion of the grown crystal, growth irregularities, etc. may cause a deviation from this shape).

Alternatively, other techniques to grow single crystals may be used such as techniques that grow a single crystal in more than one direction such as two directions, e.g. perpendicular to and along a longitudinal axis of the seed crystal or the single crystal blank to be produced.

The peripheral surface grinding step is for machining the peripheral surface in order to provide a predetermined cross-sectional shape and size to the single crystal blank and, in particular, the single crystal grown on the seed crystal.

Therefore, the peripheral surface of the single crystal blank is ground up to a first distance to the longitudinal axis. In other words, the grinding means removes material from the single crystal blank up to this first distance, i.e. the first distance defines the extension of the single crystal blank between the longitudinal axis and the peripheral surface of the single crystal blank.

Since the first distance is preferably less than an extension of the seed crystal to the longitudinal axis, i.e. between the longitudinal axis and the respective peripheral surface (in particular in the same direction starting from the longitudinal axis), the resulting cross-section of the single crystal becomes smaller than the cross-section of the seed crystal during grinding.

The peripheral surface grinding step is performed at least partially along the longitudinal axis and, in particular, along a portion of the grown single crystal in this direction (i.e. preferably excluding the portion of the longitudinal axis along the seed crystal).

For grinding the peripheral surface of the single crystal blank, a grinding means is moved relative to the peripheral surface. The relative movement is preferably performed by a relative movement between the grinding means and the single crystal blank along the longitudinal axis and/or by a relative rotation between the grinding means and the single crystal blank about the longitudinal axis (e.g. the longitudinal axis acts as a rotational axis).

Accordingly, the peripheral surface grinding step preferably machines the grown single crystal but not the seed crystal so that the seed crystal basically remains unaffected. On the one hand, the grown single crystal can be ground to have a predetermined shape and size of an ingot or a wafer to be produced from the grown single crystal. On the other hand, the seed crystal is not machined and may thus be reused (e.g. after being separated from the grown single crystal).

As described above, the portion of the single crystal blank including the grown single crystal is ground down to a first distance to the longitudinal axis that is less than an extension of the seed crystal between the longitudinal axis and the peripheral surface of the seed crystal. In other words, a first distance from the longitudinal axis to the peripheral surface of the ground single crystal is less than a second distance from the longitudinal axis to the peripheral surface of the seed crystal.

Thus, the cross-sectional shape and size of the seed crystal has a larger extension perpendicular to the longitudinal axis than the grown single crystal after the grown single crystal has been ground to a desired cross-sectional shape and size.

The peripheral surface of the single crystal blank may be ground at least partially along the longitudinal axis up to a second distance to the longitudinal axis, the second distance being greater than or substantially equal to an extension of the seed crystal to the longitudinal axis. In this case, particularly the portion of the single crystal blank along the longitudinal axis including the seed crystal is ground.

In other words, the peripheral surface of the single crystal blank may be ground at least along a seed portion of the longitudinal axis down to the second distance to the longitudinal axis, wherein the seed portion includes the seed crystal, in particular the entire seed crystal. The grinding of the peripheral surface of the single crystal blank along a seed portion of the longitudinal axis is, however, optional. In other words, the peripheral surface of the single crystal blank along a seed portion of the longitudinal axis may not be ground at all.

These approaches have the advantage to only grind the grown single crystal whereas the dimensions and shape of the seed crystal are preferably and substantially not changed during the peripheral surface grinding step. Consequently, the seed crystal may be reused for growing another single crystal of substantially the same size and shape. That is, after grinding, the seed crystal has dimensions, i.e. a longitudinal and a transversal extension such as a height and a diameter, that is sufficient for reusing the seed crystal and for growing another single crystal. The dimensions of the seed crystal are generally considered sufficient for growing another single crystal as long as it is possible to grow a single crystal with dimensions that are larger or substantially equal to the predetermined dimensions of an ingot or a wafer to be produced from the grown single crystal.

In other words, the peripheral surface grinding step is preferably not grinding the seed crystal but may only remove material from the grown single crystal. As the skilled person appreciates, there may consequently be generally no removal of material from the seed crystal except for an (insignificant) amount that may be removed during grinding residual material of the grown single crystal off (the outer surface) of the seed crystal.

Accordingly, the above proposed method may be used to grind a single crystal blank down to at least two distances along the longitudinal axis in order to keep the shape and size of the seed crystal and at the same time for the grown single crystal to have a desired shape and size.

The method preferably further comprises a wafer producing step of producing a wafer from the single crystal blank, the wafer having a predetermined thickness along (in the direction of) the longitudinal axis, wherein the wafer producing step preferably includes a step of focusing a laser beam inside the single crystal blank.

This wafer producing step provides at least one wafer having a cross-sectional profile with a shape and size that corresponds to the processed grown single crystal. Using a pulsed laser beam having a transmission wavelength to the material of the single crystal blank which is focused inside the single crystal blank for formation of modified layers allows for a cost-efficient production of a wafer with a high quality, less discarded material and reduces the amount of processing of the wafer necessary for the subsequent production of devices thereon.

The method may further comprises a seed crystal providing step of providing a seed crystal for crystal growth and a crystal growing step of growing a single crystal on at least one surface of the seed crystal for forming the single crystal blank.

This step provides the seed crystal which becomes part of the single crystal blank as a result of growing a single crystal on top of this seed crystal. As mentioned above, the single crystal is preferably at least primarily grown on a face side in the longitudinal direction of the single crystal blank.

The seed crystal provided in this step may be a seed crystal that had already been used for growing a single crystal, i.e. for producing a single crystal blank. This has the advantage that particularly seed crystals may be reused that have already shown to provide a sufficient basis for growing a single crystal with a quality required for further processing such as dividing this single crystal using a pulsed laser beam or forming optical or semiconductor devices to this single crystal.

The method preferably also includes a seed crystal separating step of separating the seed crystal from the single crystal blank and a seed crystal processing step of processing the seed crystal after the seed crystal separating step. The seed crystal processing step preferably includes grinding and/or polishing of the seed crystal.

The seed crystal is preferably separated from the single crystal blank after the grown single crystal has been shaped to have a desired shape and size. Through processing, the seed crystal may be reused to grow another single crystal for forming another single crystal blank on the basis of the separated crystal.

As a means for preparing the seed crystal for another growth process, processing of the seed crystal is preferably performed by applying a grinding step. In this step, (any) residual material of a single crystal that has previously been grown on a surface of the seed crystal is removed. In contrast and as described above, the material of the seed crystal remains substantially unaffected in this step so that the seed crystal generally keeps its shape and size.

In other words, a reuse of a seed crystal is feasible since the outer shape and dimensions of the seed crystal are basically not changed. As a result, the proposed method allows to significantly enhance the efficiency of growing single crystals since seed crystals are not discarded but are reintroduced into the production process. In addition, reusing a seed crystal is a cost efficient solution since, on the one hand side, the number of dedicated seed crystals which need to be manufactured and stocked for the growing process can be reduced and, on the other hand side, in particular those seed crystals which have shown to provide a basis for satisfying results of the grown single crystal can be reused in order to produce single crystal blanks with a high and more consistent quality.

Preparing (i.e. processing) the seed crystal for another growth process may be limited to processing only the at least one surface of the seed crystal that serves as a basis for growing the single crystal on top of the seed crystal. In particular, at least a face side of the seed crystal (facing in a longitudinal direction or primary growth direction of the seed crystal) is processed and, thus, prepared for subsequently growing another single crystal starting from the surface of this face side.

Nonetheless and depending on the method used for growing the single crystal, other surfaces may also be processed in preparation for growing another single crystal such as the peripheral surface of the seed crystal.

As already indicated above, the single crystal blank is processed for forming an ingot or a wafer, wherein the wafer is particularly separated using a laser beam, a blade and/or a wire saw.

The ingot resulting from processing the single crystal blank may be used to manufacture a single wafer. However, the single crystal blank is preferably used for producing multiple wafers. In other words, the ingot resulting from processing the single crystal blank has a thickness or length along the longitudinal axis that allows for separating at least one and preferably multiple wafers from this ingot.

The present disclosure further provides an apparatus for processing a single crystal blank, wherein the single crystal blank has a first end, a second end and a longitudinal axis extending between said first end and said second end. The single crystal blank comprises a seed crystal extending at least partially along the longitudinal axis. The apparatus comprises a peripheral surface grinding means configured to grind a peripheral surface of the single crystal blank at least partially along the longitudinal axis. The peripheral surface grinding means is particularly configured to grind the peripheral surface of the single crystal blank up to a first distance to the longitudinal axis at least partially along a portion of the longitudinal axis excluding the seed crystal, wherein the first distance is preferably less than an extension of the seed crystal to the longitudinal axis.

Due to this configuration, the apparatus according to the disclosure allows for reusing a seed crystal since the dimensions of the seed crystal are basically not modified during the processing of the single crystal blank.

Accordingly, the peripheral surface grinding means of the apparatus may further be configured to grind the peripheral surface of the single crystal blank at least partially along the longitudinal axis up to a second distance to the longitudinal axis, the second distance being greater than or substantially equal to an extension of the seed crystal to the longitudinal axis (i.e. a distance between a point on the peripheral surface of the seed crystal and the longitudinal axis).

Further, the peripheral surface grinding means may be configured to grind the peripheral surface of the single crystal blank at least along a seed portion of the longitudinal axis up to the second distance to the longitudinal axis, wherein the seed portion includes the seed crystal, in particular the entire seed crystal.

The apparatus may also perform a separating step of separating the seed crystal from a grown single crystal on the basis of this seed crystal.

Preferably, the apparatus is also configured to perform processing on the seed crystal separated from a grown single crystal as described above for preparing the seed crystal as a basis for growing another single crystal, i.e. to form another single crystal blank.

As part of processing the single crystal blank, the grinding means may be configured to also grind at least the face side of the grown single crystal facing along the longitudinal direction away from the seed crystal. In other words, the face side to be ground is on the side of the single crystal blank opposite to the end where the seed crystal is located.

According to any one of the aspects described above, the method and the apparatus both allow to enhance the production of single crystals to be used for different kinds of semiconductor and/or optical devices while ensuring a sufficient quality and driving manufacturing costs down.

### BRIEF DESCRIPTION OF THE FIGURES

The following figures illustrate examples of a method for processing a single crystal blank and parts of an apparatus for processing a single crystal blank according to the present disclosure. In these figures, same reference signs refer to features throughout the drawings that have the same or an equivalent function and/or structure. It is to be understood that the figures illustrate examples of the method and the apparatus according to the present disclosure without limiting the invention thereto.

FIGS. 1A to 1F are cross-sectional views of a single crystal blank along a longitudinal axis and illustrate successive steps of an exemplary method for processing a single crystal blank according to the present disclosure.

FIGS. 2A to 2D are cross-sectional views of a single crystal blank along a longitudinal axis and illustrate different embodiments of a peripheral surface grinding step in a method for processing a single crystal blank as well as different embodiments of a grinding means of an apparatus for processing a single crystal blank according to the present disclosure.

FIG. 3 is a top view of a single crystal blank and illustrates an orientation flat formed on the peripheral surface of the grown single crystal.

FIG. 4A is a cross-sectional view of a single crystal blank along a longitudinal axis and illustrates a seed crystal processing step in a method for processing a single crystal blank and means for processing of a seed crystal according to the present disclosure.

FIG. 4B is a cross-sectional view of a single crystal blank along a longitudinal axis and illustrates a crystal growth step in a method for processing a single crystal blank according to the present disclosure.

### DETAILED DESCRIPTION OF PREFERRED EMBODIMENTS

The method and the apparatus for processing a single crystal blank according to the present disclosure are further described in more detail with reference to the accompanying figures.

The method and the apparatus described herein generally refer to the processing of a single crystal blank 10. Processing of a single crystal blank 10 may be necessary for forming an ingot that may in turn be used to form a single wafer 30 or several wafers 30.

Figures LA to 1F are cross-sectional views of a single crystal blank 10 along a longitudinal axis 13. The single crystal blank comprises a first end 11, a second end 12 and a longitudinal axis 13 extending between said first and said second ends 11 and 12. The single crystal blank 10 further comprises a peripheral surface 14 which surrounds the longitudinal axis 13.

It is preferred that the single crystal blank 10 is substantially cylindrically shaped and has the cylindrical shape at least partially along the longitudinal axis 13. Moreover, the single crystal blank 10 has a cross-section perpendicular to the longitudinal axis 13 with an outline that is preferably substantially round or oval or, even more preferably, substantially circular. The term “substantially” is used since by the nature of producing the single crystal blank 10 (as further explained below) the shape of the single crystal blank 10 along the longitudinal axis 13 and/or the outlines of the cross-sections may deviate from a desired predefined shape. The single crystal blank 10 may also comprise at least one linear section (e.g. an orientation flat 18, a shape with at least one linear section such as a rectangular shape, etc.) along the outline of its cross-section.

The single crystal blank 10 may be made of a semiconductor material, e.g. silicon carbide (SiC), silicon (Si), diamond, gallium nitride (GaN), gallium arsenide (GaAs), gallium oxide (Ga₂O₃), aluminium nitride (AlN), sapphire, etc.

In particular, the single crystal blank 10 may be, for example, a Si single crystal blank 10, a GaAs single crystal blank 10, a GaN single crystal blank 10, a Ga₂O₃ single crystal blank 10, a SiC single crystal blank 10 or the like.

From such a single crystal blank 10 comprising a semiconductor material, semiconductor ingots or semiconductor wafers 30 may be formed. On such semiconductor wafers 30, devices such as power devices and/or ICs (integrated circuits) and/or LSIs (large scale integrations) may be formed.

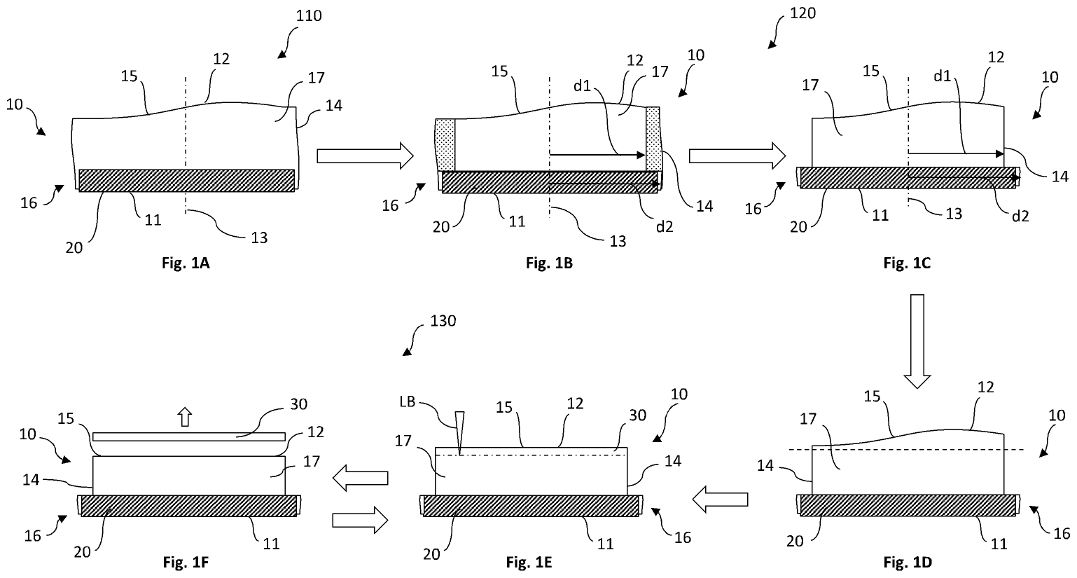

As schematically illustrated in FIG. 1A, the single crystal blank 10 is preferably formed by crystal growth (e.g. epitaxial growth).

The method according to the present disclosure preferably comprises a seed crystal providing step of providing a seed crystal 20 to grow a single crystal thereon. In particular, the seed crystal 20 may be provided to an apparatus which is configured to grow a single crystal (in particular to form a single crystal blank 10) on a surface of the seed crystal 20. This means that at least one side of the seed crystal 20 may be attached to an apparatus so that at least one surface side of the seed crystal 20 is exposed.

The method according to the present disclosure may further comprise a crystal growing step 110 of growing the single crystal blank 10 on an exposed surface of the seed crystal 20. As described above, this exposed surface is preferably a face side surface of the seed crystal 20.

The apparatus according to the present disclosure may, thus, comprise a holding means configured to hold a seed crystal 20 for crystal growth. That is, the apparatus may comprise at least one interface section to which at least one surface of the seed crystal 20 can be attached to such that at least one other surface of the seed crystal 20 is exposed to a source of substrate. The apparatus may further comprise a means for growing a single crystal on a surface of the seed crystal in order to form a single crystal blank 10.

The seed crystal 20 is not limited to a specific shape. That is, the seed crystal 20 may be cylindrical and/or plate-shaped and may comprise cross-sections with outlines that are substantially round, oval or circular. However, the seed crystal 20 may also comprise at least one linear section along the outline of the cross-sections. In particular, the seed crystal 20 may also be a square or rectangular, preferably plate-shaped body. Plate-shaped in the present context means that the seed crystal 20 comprises a thickness, i.e. a longitudinal extension, which is significantly lower than a transversal extension, e.g. a diameter, of the seed crystal 20.

The seed crystal 20 may have a larger longitudinal and/or transversal extension than a single wafer 30. It is particularly preferred that the seed crystal 20 comprises a longitudinal extension or thickness of at least or substantially 1 mm. Moreover, the seed crystal 20 preferably comprises a transversal extension and/or diameter of e.g. 151 mm, when the transversal extension and/or diameter of the single wafer 30 to be produced from the single crystal blank 10 is 150 mm, or 201 mm, when the transversal extension and/or diameter of the single wafer to be produced from the single crystal blank 10 is 200 mm. The seed crystal 20 is, however, not limited to these specific sizes. In more general terms, the seed crystal 20 preferably comprises larger dimensions (i.e. a transversal extension, such as a diameter, and/or a longitudinal extension) than the predetermined dimensions of the wafers to be produced from the single crystal blank 10. For example, the transversal and/or longitudinal extension of the seed crystal 20 may be 0.5 to 5 mm, preferably 0.5 to 2 mm or even more preferably substantially 1 mm larger than the predetermined transversal and/or longitudinal extension of the wafer 30. As described above, the seed crystal 20 is preferably formed of the same material as the single crystal blank 10.

The seed crystal 20 and, in particular, the quality of the seed crystal 20 is crucial for the production quality of the single crystal blank 10. The quality of the seed crystal 20 in the present context refers to, inter alia, the purity of the material and the order of the crystal structure of the seed crystal 20. Without wishing to be bound by theory, it is believed that during the crystal growing step 110 the single crystal blank 10 is formed with the same or at least similar quality as the seed crystal 20. Thus, a high quality of the seed crystal 20 generally also results in a high quality of the grown single crystal blank 10. The quality of a seed crystal 20 required for the production of a single crystal blank 10 is, thus, relatively high.

The single crystal blank 10 is typically grown to an extension along the longitudinal axis in the range of 0.5 mm to 50 mm. The method is, however, not limited to the above-mentioned range for the longitudinal extension of the single crystal blank 10. Therefore, the single crystal blank 10 may also have a longitudinal extension greater than or less than the above-mentioned range.

As further illustrated in FIGS. 1A to 1F, due to the nature of producing the single crystal blank 10, the seed crystal 20 may partially be encompassed by the single crystal 17 grown on the seed crystal 20. The single crystal blank 10, thus, comprises the seed crystal 20 which extends partially along the longitudinal axis 13 of the single crystal blank 10 and the grown single crystal 17. The seed crystal 20 is preferably positioned at a first end 11 of the single crystal blank 10. The single crystal blank 10 comprises a seed portion 16 along the longitudinal axis 13, wherein the seed portion 16 includes the seed crystal 20, in particular the entire seed crystal 20. In other words, the seed crystal 20 does preferably not extend beyond the seed portion 16 of the single crystal blank 10.

The single crystal blank 10 comprises (or consists of) the seed crystal 20 and the grown single crystal 17 which are distinguishable (e.g. based on purity of the crystal, dimensions, etc.). The seed crystal 20 further typically distinguishes from the grown single crystal 17 in that, by the nature of the process, the seed crystal 20 is of a higher quality, e.g. with respect to defects of the crystal orientation, than the grown single crystal 17. In other words, as the crystal growth process progresses, the quality of the growing crystal may deteriorate. Therefore, it is of interest to maintain the original seed crystal 20 to allow for reusage of the seed crystal 20 for crystal growth. An interface of the seed crystal 20 and the grown single crystal 17 may also be determinable by x-ray crystallography.

The single crystal blank 10 is, according to its name, a blank (or, in other words, a workpiece) which is to be processed to form an ingot and/or one or more wafers 30. However, the single crystal blank 10 does preferably not include any devices formed on the surface thereof.

As further shown in FIGS. 1B and 1C, the method of processing a single crystal blank 10 comprises the step of a peripheral surface grinding step 120 of grinding the peripheral surface 14 of the single crystal blank 10 so that the single crystal blank is at least partially ground along the longitudinal axis 13. In other words, in this peripheral surface grinding step 120, a transversal extension of the single crystal blank 10 relative to the longitudinal axis 13, e.g. a diameter of the single crystal blank 10, is reduced at least partially along the longitudinal axis 13 of the single crystal blank 10. As schematically illustrated in the exemplary embodiment of FIGS. 1B and 1C, the dotted areas of the single crystal blank 10 are to be ground off.

The peripheral surface 14 of the single crystal blank 10 is ground by a peripheral surface grinding means which is configured to grind the peripheral surface 14 of the single crystal blank 10 at least partially along the longitudinal axis 13. Thus, the apparatus according to the present disclosure comprises such a peripheral surface grinding means.

The apparatus may further comprise a chuck table (not shown) at which the single crystal blank 10 may be held (e.g. fixed) via at least one surface of the single crystal blank 10 during grinding of the peripheral surface 14. Preferably, the single crystal blank 10 is held on the chuck table via the first end 11 of the single crystal blank 10. That is, it is preferably the end of the single crystal blank 10 where the seed crystal 20 is located that is held on the chuck table.

The single crystal blank 10 may be held on the chuck table by means of a vacuum which is applied to the surface of the chuck table. Alternatively or additionally, the single crystal blank 10 may be held on the chuck table by clamping means. Moreover, it is also possible that the single crystal blank 10 is held on the chuck table via a tape or a tape and a frame which is attached to the single crystal blank 10. Moreover, it is also possible that the single crystal blank 10 is held on the chuck table via a supporting substrate or a supporting substrate and a frame which is attached to the single crystal blank 10. The chuck table may be further configured to be movable along two or three dimensions and to be rotatable around its longitudinal axis.

The apparatus according to the present disclosure may further use the same chuck table to hold the single crystal blank 10 during the subsequent method steps (as further described below). The apparatus may, alternatively, further comprise additional chuck tables that are similar to the chuck table described above to hold the single crystal blank 10 during subsequent method steps. For reasons of conciseness, it may not be explicitly referred to a chuck table hereinafter.

Through grinding of the peripheral surface 14 of the single crystal blank 10, irregularities of the single crystal blank 10 resulting from the crystal growth, e.g. a varying transversal extension along the longitudinal axis 13, are preferably removed. This means that protrusions and/or recesses on the peripheral surface 14 of the single crystal blank 10 resulting from the crystal growth and representing deviations of a desired shape of the ingot are substantially removed. Moreover, the transversal extension of the single crystal blank 10 along the longitudinal axis 13 is machined to be uniform at least partially along the longitudinal axis 13 such that ingots or wafers 30 of substantially equal dimensions, i.e. transversal extensions such as, for example, diameters, can be formed from the single crystal blank 10.

The peripheral surface 14 of the single crystal blank 10 may be ground to have any predefined shape along the longitudinal axis 13 and/or a predefined outline perpendicular to the longitudinal axis 13. That is, the peripheral surface 14 of the single crystal blank 10 may be ground such that the single crystal blank 10 has a cylindrical shape extending at least partially along the longitudinal axis 13. The peripheral surface 14 of the single crystal blank 10 may also be ground so that an outline of the cross-section of the single crystal blank is substantially round, oval or circular. A cross-sectional outline of the cross-section of the single crystal blank 10 may further comprise at least one linear section and, in particular, may have a square or rectangular shape after grinding.

It is particularly preferred that the peripheral surface 14 of the single crystal blank 10 is ground according to a desired transversal extension or a desired cross-sectional outline of a wafer 30 to be formed from the single crystal blank 10.

The peripheral surface 14 of the single crystal blank is ground up to a first distance d1 to the longitudinal axis 13, wherein grinding is performed at least partially along a portion of the longitudinal axis 13 excluding the seed crystal 20. This means that the grinding of the peripheral surface 14 of the single crystal blank 10 up to a first distance d1 is performed at least partially along a portion of the longitudinal axis 13 of the single crystal blank 10 where the seed crystal 20 is not present. In other words, the grinding of the peripheral surface 14 of the single crystal blank 10 up to a first distance d1 to the longitudinal axis 13 is preferably not performed along a portion of the longitudinal axis 13 of the single crystal blank 10 including the seed crystal 20.

The first distance d1 is measured from the longitudinal axis 13 to the peripheral surface 14 of the single crystal blank 10 in a direction perpendicular to the longitudinal axis 13. Grinding up to a first distance d1 means that the single crystal blank 10 comprises at least one portion along the circumference having a transversal extension that is equal to the first distance d1 at this grinding position after the peripheral surface grinding step 120 has finished. The grinding position is defined by a position along the longitudinal axis 13 of the single crystal blank 10 (i.e. the shape of the single crystal blank 10 is processed to be cylindrical). This does, however, not exclude that there may be one or more portions along the circumference of the single crystal blank 10 relating to this grinding position with transversal extensions that are smaller or greater than the first distance d1 (e.g. the single crystal blank 10 is ground to have a substantially circular, rectangular, square, etc. cross-section).

Preferably, during the peripheral surface grinding step 120, the peripheral surface 14 of the single crystal blank 10 is substantially equally ground up to the first distance d1 along the (entire) circumference of the single crystal blank 10 at least partially along the longitudinal axis 13. In other words, after the peripheral surface grinding step 120 has finished, the single crystal blank 10 comprises the same transversal extension, preferably the first distance d1, around the (entire) circumference at least partially along the longitudinal axis 13 which results in a substantially cylindrical shape of the single crystal blank 10 at least partially along the longitudinal axis 13.

The first distance d1 is preferably less than an extension of the seed crystal 20 to the longitudinal axis (i.e. less than an extension of the seed crystal 20 between the longitudinal axis and the circumference of the seed crystal 20). Preferably, the first distance d1 is the desired distance to the longitudinal axis 13 of a wafer 30 to be separated from the single crystal blank 10.

The apparatus according to the present disclosure and, in particular, the peripheral surface grinding means of the apparatus is configured to perform grinding of the peripheral surface 14 of the single crystal blank up to the first distance d1 as described above.

Since grinding of the peripheral surface 14 of the single crystal blank 10 is performed along a portion of the longitudinal axis 13 excluding the seed crystal 20, it is possible to avoid grinding of the seed crystal 20. Thereby, the original dimensions, i.e. thickness and transversal extension (e.g. diameter), of the seed crystal 20 remain unchanged. This provides the advantageous effect that the seed crystal 20 may be reused for further crystal growth steps. In other words, it is possible to reuse the same seed crystal 20 for the method steps described herein.

This not only allows a more constant production quality of the single crystal blanks 10, the ingots and the single wafers 30 formed therefrom but also the repeated use of seed crystals 20 having a high quality. This is particularly desired as the overall manufacturing quality of the single crystal blanks 10 and, thus, the ingots and wafers 30 produced therefrom can be improved, maintained and be kept consistent.

As the seed crystals 20 have a significant influence on the quality of the grown single crystal 17 and, thus, on the ingot and the single wafers 30 formed therefrom, the quality requirements of the seed crystals 20 are typically very high and the seed crystals 20 are, thus, very expensive. Reusage of the seed crystals 20, therefore, also allows cost savings and, thus, an improvement of production efficiency. In addition, the reuse or recycling of seed crystals 20 allows to reduce more cost intensive process steps for growing seed crystals 20. Thereby, cost savings can be realized and the production efficiency can be improved even further.

In addition, optionally, the peripheral surface 14 of the single crystal blank 10 is ground at least partially along the longitudinal axis 13 up to a second distance d2 to the longitudinal axis 13, the second distance d2 being greater than or substantially equal to an extension of the seed crystal 20 to the longitudinal axis 13 (i.e. an extension of the seed crystal between the longitudinal axis 13 and the outer side of the seed crystal 20). In other words, the peripheral surface 14 of the single crystal blank 10 along the longitudinal axis 13 may be ground to different diameters, i.e. a second distance d2 and a first distance d1.

As illustrated in FIG. 1C, after grinding has been performed, the single crystal blank 10 comprises portions along the longitudinal axis 13 having different transversal extensions, i.e. extensions perpendicular to the longitudinal axis 13.

The second distance d2 is measured from the longitudinal axis 13 to the peripheral surface 14 or outer side of the single crystal blank 10 in a direction perpendicular to the longitudinal axis 13. Similar to the description above with respect to the first distance d1, grinding up to a second distance d2 means that the single crystal blank 10 comprises at least one portion along the circumference having a transversal extension that is equal to the second distance d2 at this grinding position after grinding (i.e. the shape of the single crystal blank 10 is processed to be cylindrical) and does not exclude that there may be one or more portions along the circumference of the single crystal blank 10 relating to this grinding position with transversal extensions that are smaller or greater than the second distance d2 (e.g. the single crystal blank 10 is ground to have a substantially circular, rectangular, square, etc. cross-section).

Accordingly, the peripheral surface grinding means of the apparatus according to the present disclosure may be configured to perform grinding of the peripheral surface 14 of the single crystal blank 10 up to the second distance d2.

The peripheral surface 14 of the single crystal blank may be ground at least along the seed portion 16 of the longitudinal axis 13 up to the second distance d2 to the longitudinal axis 13, the seed portion 16 including the seed crystal 20, in particular the entire seed crystal 20. Alternatively, the peripheral surface 14 of the single crystal blank 10 along the seed portion 16 of the longitudinal axis 13 may not be ground (at all).

The peripheral surface grinding means of the apparatus according to the present disclosure may further be configured to perform grinding of the peripheral surface 14 of the single crystal blank 10 at least along the seed portion 16 of the longitudinal axis 13 up to the second distance d2.

In other words, the peripheral surface 14 of the single crystal blank 10 may only be ground along the seed crystal 20, i.e. along the longitudinal axis 13 where the seed crystal 20 is present, up to a second distance d2 (or is not ground at all) such that the original dimensions of the seed crystal 20 are not changed. This ensures that the seed crystal 20 maintains its original size such that the seed crystal 20 can be reused for subsequent production cycles.

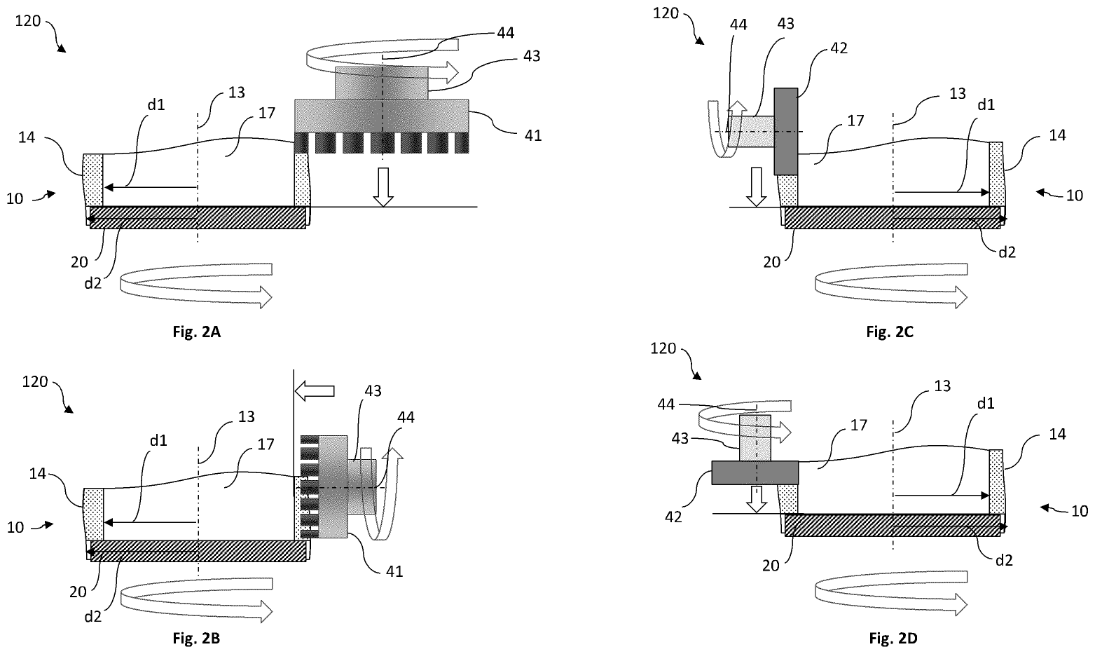

In FIGS. 2A to 2D, different embodiments of a peripheral surface grinding step 120 and different embodiments of a peripheral surface grinding means according to the present disclosure are illustrated. As shown in FIGS. 2A and 2B, a grinding wheel 41 is used for grinding the peripheral surface 14 of the single crystal blank 10. The grinding wheel 41 may comprise a bottom surface to which abrasive members (or precision diamond abrasive members, such as abrasive members having a smaller size for fine grinding) are attached. The abrasive members are configured to grind the substrate of the single crystal blank 10. The abrasive members are preferably ring-shaped or are aligned in a ring-shape on the grinding wheel 41 with or without a space in between single abrasive members. The ring-shaped abrasive members may be interrupted at least once along the circumference or may be not interrupted at all. The grinding wheel 41 may comprise exactly one ring of abrasive members.

The grinding wheel 41 is mounted on a spindle 43 which defines a spindle axis 44 (i.e. a longitudinal axis) of the grinding wheel 41 as an axis of rotation. Upon rotation of the spindle, the rotational movement is transferred to the grinding wheel 41. The spindle axis 44 and a feed direction (i.e. a moving direction during the grinding process) of the grinding wheel 41 may be aligned substantially parallel to the longitudinal axis 13 (as shown in FIG. 2A) or may be aligned substantially perpendicular to the longitudinal axis 13 (as shown in FIG. 2B). In other words, the feed direction is preferably either directed (radially) inwards from the peripheral surface 14 of the single crystal blank (illustrated in FIG. 2B) or may be directed towards an end of the single crystal blank 10 where the seed crystal is located (or, in other words, directed towards the chuck table) (illustrated in FIG. 2A). In both cases, either the grinding wheel 41, the single crystal blank 10 held on the chuck table via the first end 11 of the single crystal blank 10 or both the grinding wheel 41 and the single crystal blank 10 held on the chuck table may perform a rotational movement around their respective longitudinal axes. The rotational directions illustrated in FIGS. 2A and 2B should be understood as an example and should not be considered limiting. In other words, one or both of the grinding wheel 41 and the single crystal blank 10 held on the chuck table can be rotated in either direction.

As further illustrated in FIGS. 2C and 2D, a dicing blade 42 may be used for the peripheral surface grinding step 120. The dicing blade 42 comprises abrasive members (or precision diamond abrasive members) which are preferably annularly arranged along the circumference of the dicing blade 42. The abrasive members may be configured to perform cutting by grinding the substrate of the single crystal blank 10.

The dicing blade 42 is mounted on a spindle 43 which defines a spindle axis 44 (i.e. a longitudinal axis) of the dicing blade 42 as an axis of rotation. Upon rotation of the spindle, the rotational movement is transferred to the dicing blade 42. The spindle axis 44 may be aligned substantially perpendicular to the longitudinal axis 13 (as shown in FIG. 2C) or may be aligned substantially parallel to the longitudinal axis 13 (as shown in FIG. 2D). In both cases, however, the feed direction of the dicing blade 42 is preferably substantially parallel to the longitudinal axis 13 and directed towards the end of the single crystal blank 10 where the seed crystal 20 is located (or, in other words, directed towards the chuck table). Further, either the dicing blade 42, the single crystal blank 10 held on the chuck table via the first end 11 or the second end 12 of the single crystal blank 10 or both the dicing blade 42 and the single crystal blank 10 held on the chuck table may perform a rotational movement around their respective longitudinal axes. The rotational directions illustrated in FIGS. 2C and 2D should be understood as an example and should not be considered limiting. In other words, one or both of the dicing blade 42 and the single crystal blank 10 held on the chuck table can be rotated in either direction.

The method according to the present disclosure may further comprise an orientation flat grinding step (not shown) of grinding one or more, for example two, orientation flats 18 on the peripheral surface 14 of the single crystal blank 10 at least partially along the longitudinal axis 13. An orientation flat 18 is a linear section along the circumference of the single crystal blank 10. The orientation flat 18 is generally used to indicate the crystal orientation of the material of the grown single crystal 17. The crystal orientation of the material of the grown single crystal 17 may be detected by various ways known in the prior art, for example x-ray diffraction analysis (x-ray crystallography).

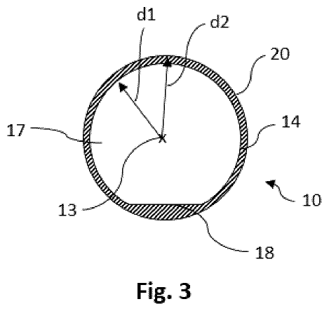

FIG. 3 is a top view of the single crystal blank 10 in a state after an orientation flat grinding step has been performed. The orientation flat grinding step is preferably performed along a portion of the longitudinal axis 13 excluding the seed crystal 20, in particular along the portion of the longitudinal axis 13 along which the peripheral surface grinding step 120 is performed. In other words, the orientation flat grinding step is preferably not performed along a portion of the longitudinal axis 13 of the single crystal blank 10 including the seed crystal 20. As exemplarily illustrated in FIG. 3, an orientation flat 18 is (only) formed on the peripheral surface 14 of the grown single crystal 17 while no orientation flat 18 is formed on the seed crystal 20. Thereby, the original size of the seed crystal 20 is not altered, i.e. the seed crystal maintains its original, preferably circular, shape.

The orientation flat grinding step may be performed by an accordingly configured grinding means, particularly by a grinding wheel 41 or by a dicing blade 42, of the apparatus according to the present disclosure. The peripheral surface grinding means may also be further configured to perform the orientation flat grinding step. Moreover, the orientation flat grinding step may be performed prior to or subsequently to the peripheral surface grinding step 120. An orientation flat grinding step is, however, optional. Accordingly, in such a case no orientation flat 18 is formed on the single crystal blank at all.

According to the present disclosure and as shown in FIG. 1D, the method according to the present disclosure may further comprise a grinding step of grinding the top surface 15 of the single crystal blank 10 (top surface grinding step). It is particularly preferred that the top surface 15 of the single crystal blank 10 is flattened in this grinding step such that the first end 11 and the second end 12 of the single crystal blank 10 are made substantially parallel (as illustrated as a dashed line in FIG. 1D). A top surface 15 in the present context refers to the end surface at the first or second end 11, 12 of the single crystal blank 10 opposite to the end where the seed crystal is located. The top surface 15 of the single crystal blank 10 is the free end of the single crystal blank 10 which is not held on a chuck table and which is, thus, exposed to be processed.

The grinding step may be performed by the same grinding means used during the peripheral surface grinding step 120. The peripheral surface grinding means of the apparatus according to the present disclosure may, thus, be further configured to perform grinding of the top surface 15 of the single crystal blank 10. The apparatus may, alternatively, also comprise a second grinding means configured to perform this grinding step.

By grinding the top surface 15 of the single crystal blank 10, one end face of the single crystal blank 10 is processed such that the end faces at the first end 11 and the second end 12 are aligned substantially in parallel. Moreover, irregularities of the single crystal blank 10 that result from crystal growth of the single crystal blank are removed. Thereby, at least one wafer 30 with a substantially equal or at least similar dimensions can be formed from the single crystal blank 10 (or ingot after the grinding steps).

The top surface grinding step may be performed before or after the peripheral surface grinding step 120. In particular, a flattening of the top surface 15 of the single crystal blank 10 may preferably be performed prior to grinding of the peripheral surface 14 of the single crystal blank 10, particularly in those cases where the single crystal blank 10 comprises significant irregularities.

Grinding of the top surface 15 or face side prior to grinding of the peripheral surface is particularly preferred in cases, in which the peripheral surface grinding step 120 is performed by the grinding wheel 41, wherein the longitudinal axis of the grinding wheel 41 is aligned parallel to the longitudinal axis 13 (as illustrated in FIG. 2A). Grinding the top surface 15 or face side prior to peripheral surface grinding may also be preferred when the peripheral surface grinding step 120 is performed by the dicing blade 42 (as illustrated in FIGS. 2C and 2D). Moreover, for setting the start position of the peripheral surface grinding means before the peripheral surface grinding step 120 is started, a flattening of the top surface 15 of the single crystal blank 10 to a defined longitudinal extension of the single crystal blank 10 is preferred.

Moreover, applying the top surface grinding step before the peripheral surface grinding step 120 is advantageous in view of a uniform removal of material and load applied to the single crystal blank 10. Thereby, irregularities applied to the single crystal blank 10 during grinding are prevented and the vertical distance of the peripheral surface grinding means to the chuck table (i.e. the distance along the longitudinal axis 13) can be equalized.

Performing the grinding of the top surface 15 prior to irradiating the grown single crystal 17 with a laser beam LB during the wafer producing step 130 (as further explained below) is particularly preferred as it allows a proper application of the laser beam LB at a desired depth in the single crystal 17.

A fine grinding step may be performed on the peripheral surface 14 of the single crystal blank 10 as a second grinding step additionally to the peripheral surface grinding step 120. In other words, the peripheral surface grinding step 120 may be performed as a coarse grinding step after which the fine grinding step on the peripheral surface 14 of the single crystal blank 10 may subsequently be performed.

In a similar manner, a fine grinding step may also be performed on the top surface 15 of the single crystal blank 10 additionally to the top surface grinding step. In other words, the top surface grinding step may be performed as a coarse grinding step after which the fine grinding step on the top surface 15 of the single crystal blank 10 may subsequently be performed.

The apparatus according to the present disclosure may, thus, comprise a grinding means which is configured to perform fine grinding on the peripheral surface 14 and/or the top surface 15 of the single crystal blank 10. Alternatively, the fine grinding step may also be performed by the peripheral surface grinding means or by the grinding means used for grinding the top surface 15 of the single crystal blank 10.

A fine grinding of the peripheral surface 14 of the single crystal blank 10 allows for achieving a desired grinding result, e.g. a desired surface roughness, on the peripheral surface 14 of the single crystal blank 10. In other words, during the peripheral surface grinding step 120 the peripheral surface 14 of the single crystal blank may be ground up to the desired dimensions of the single crystal blank 10 and, subsequently, fine grinding may be performed on the peripheral surface 14 to achieve the desired quality of the surface.

As further illustrated in FIGS. 1E and 1F, the method according to the present disclosure may further comprise a wafer producing step 130 of producing a wafer from the single crystal blank 10. The wafer 30 produced from the single crystal blank 10 has a predetermined thickness along the longitudinal axis 13. The wafer producing step 130 is preferably performed using a pulsed laser beam. The wafer producing step 130 may include a step of focusing a pulsed laser beam LB which has a transmission wavelength to the material of the single crystal blank 10 inside the single crystal blank 10, preferably at a distance from the top surface 15 of the single crystal blank 10 which corresponds to the predetermined thickness of the wafer 30.

Without wishing to be bound by theory, by focusing the laser beam LB inside the single crystal blank 10 and moving the laser beam LB and the single crystal blank 10 relative to each other, a plurality of modified regions are formed inside the material.

The modified regions may comprise amorphous regions or regions in which cracks are formed, or may be amorphous regions or regions in which cracks are formed. In particularly preferred embodiments, the modified regions comprise or are amorphous regions. The plurality of modified regions form a separation layer along which a wafer 30 may be separated from the single crystal blank 10.

The wafer 30 may be separated from the single crystal blank 10 after applying the laser beam LB by applying an external force to the top surface 15 of the single crystal blank 10 and/or the entire single crystal blank 10. Applying the external force to the single crystal blank 10 may comprise or consist of applying an ultrasonic wave to the single crystal blank 10. The wafer 30 may also be separated from the single crystal blank 10 in other ways known in the prior art, such as cutting with a wire saw.

The apparatus according to the present disclosure may, thus, comprise a means which is configured to produce a wafer 30 from the single crystal blank 10. In particular, the apparatus may comprise a laser beam applying means which is configured to apply a laser beam LB inside the single crystal blank 10 for formation of a separation layer. Further, the apparatus may comprise a means which is configured to separate the wafer 30 from the single crystal blank 10. Alternatively, the apparatus may comprise a wire saw which is configured to produce a wafer 30 from the single crystal blank 10.

The wafer 30 formed from the single crystal blank 10 may have any shape. In a top view thereon, the wafer 30 may have, for example, a circular shape, an oval shape, an elliptical shape or a polygonal shape, such as a rectangular shape or a square shape.

The wafer 30 may further be a semiconductor-sized wafer. Herein, the term “semiconductor-sized wafer” refers to a wafer 30 with the dimensions (standardised dimensions), in particular, the diameter (standardised diameter), i.e., outer diameter, of a semiconductor wafer. The dimensions, in particular, the diameters, i.e., outer diameters, of semiconductor wafers are defined in the SEMI standards. For example, the dimensions of polished single crystal silicon (Si) wafers are defined in the SEMI standards M1 and M76 and the dimensions of polished single crystal silicon carbide (SiC) wafers are defined in the SEMI standard M55. The semiconductor-sized wafer may be a 3 inch, 4 inch, 5 inch, 6 inch, 8 inch, 12 inch or 18 inch wafer.

According to the present disclosure, the wafer 30 preferably has a final diameter of substantially 150 mm or 200 mm.

The wafer producing step 130 may be repeated to form a plurality of wafers 30 from the single crystal blank 10. Preferably, the wafer producing step 130 is no longer repeated once the focusing of the laser beam LB would occur inside the seed crystal 20. In other words, the wafer producing step 130 is no longer repeated once no further wafer 30 with the predetermined thickness can be separated from the single crystal blank 10 without damaging the seed crystal 20.

Thereby, the original dimensions of the seed crystal 20 are substantially not changed which would adversely affect the reusability of the seed crystal 20. Moreover, the quality of the seed crystal 20 is maintained. This leaves the seed crystal 20 intact for its reuse for another production cycle.

After the separation of a single wafer 30 from the single crystal blank 10 during the wafer producing step 130 and prior to a subsequent wafer producing step 130 for separation of another single wafer 30 from the single crystal blank 10, the (newly exposed) top surface 15 of the single crystal blank 10 may be ground in a further grinding step (not shown). This grinding step of grinding the top surface 15 of the single crystal blank 10 in between subsequent wafer producing steps 130 may be substantially in accordance with the top surface grinding step. The grinding step of grinding the top surface 15 of the single crystal blank 10 in between subsequent wafer producing steps 130 may be performed as a coarse grinding step and a subsequent fine grinding step.

Grinding of the top surface 15 of the single crystal blank 15 may be performed with an accordingly configured grinding means of the apparatus according to the present disclosure, preferably by the same grinding means as disclosed with respect to the top surface grinding step with respect to FIG. 1D.

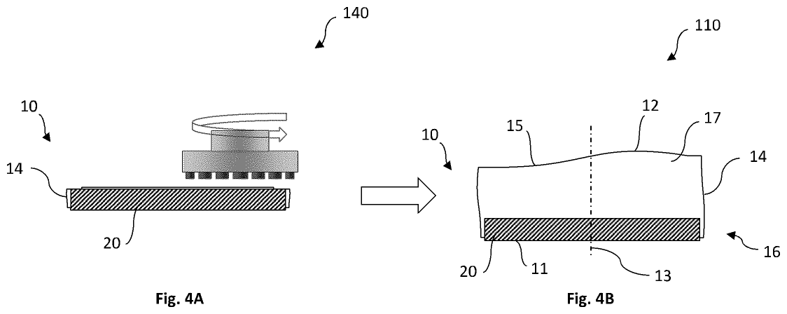

FIG. 4A illustrates a single crystal blank 10 after the wafer producing step 130 has been performed a plurality of times in order to separate a plurality of single wafers with a predetermined thickness from the single crystal blank 10. In the state of the single crystal blank 10 illustrated in FIG. 4A, no further single wafer 30 with a predetermined (i.e. desired) thickness can be separated from the single crystal blank 10 without damaging the seed crystal 20 and the single crystal blank 10 essentially consists of the seed crystal 20 and residual material from the crystal growing step 110 or from the grown single crystal 17 which is integral with the surface of the seed crystal 20. In other words, the residual material is the material which attaches to the surface of the seed crystal in the state when no further wafer producing step 130 can be carried out without altering the original dimensions of the seed crystal 20.

Thus, prior to reusing the seed crystal 20, processing of the seed crystal 20 may be necessary in order to remove the residual material from the seed crystal 20 whereby essentially the original seed crystal 20 is obtained and/or exposed. The method may, therefore, further comprise a seed crystal processing step 140 of processing the seed crystal to remove residual grown single crystal material which is illustrated in FIG. 4A.

During the seed crystal processing step 140, the residual material from the crystal growing step 110 which attaches to the circumference of the seed crystal 20 may (or may not) be removed. For reusage of the seed crystal it is beneficial that the face side of the seed crystal is essentially free from any residual material. In other words, the seed crystal 20 is processed, e.g. ground, to a degree that no adverse effects are caused by residual material of the grown crystal 17.

The processing of the seed crystal may be performed by grinding and/or polishing of the seed crystal 20. It is also possible that the processing of the seed crystal is performed by cutting and/or etching, e.g. by a chemical agent or by plasma (for example, dry etching). The seed crystal 20 obtained from the seed crystal processing step 140 may then be used in a subsequent crystal growing step 110, as illustrated in FIG. 4B.

The apparatus according to the present disclosure, thus, comprises a means configured for processing of the seed crystal 20. The grinding means used during the peripheral surface grinding step 120 and/or the top surface grinding step may also be further configured for processing the seed crystal 20.

It is, thus, possible to obtain a seed crystal 20 of substantially the same size and quality the seed crystal had for the antecedent crystal growing step 110. In other words, the seed crystal 20 from an antecedent crystal growing step 110 can be reused for a subsequent crystal growing step 110 while retaining the quality, properties and substantially the same dimensions of the seed crystal 20. The term “substantially” is used as, by the nature of the process of processing the seed crystal 20 and in order to remove residual material which attaches to the surface of the seed crystal 20, the seed crystal 20 is (although not intended) also ground to a very small amount.

This allows cost savings as the seed crystal 20 is almost not lost, i.e. only an insignificant amount of material of the seed crystal 20 is removed, during production and can, thus, be used multiple times. Moreover, it is possible to maintain a seed crystal 20 of good quality for further production steps to improve and maintain manufacturing quality.

### REFERENCE SIGNS

10 single crystal blank
11 first end
12 second end
13 longitudinal axis
14 peripheral surface
15 top surface
16 seed portion
17 single crystal
18 orientation flat
20 seed crystal
30 wafer
41 grinding wheel
42 dicing blade
43 spindle
44 spindle axis
110 crystal growing step
120 peripheral surface grinding step
130 wafer producing step
140 seed crystal processing step
LB laser beam
d1 first distance
d2 second distance

1. A method for processing a single crystal blank, the single crystal blank having a first end, a second end extending between the first end and the second end wherein the single crystal blank includes a seed crystal and a single crystal, the seed crystal extending at least partially along the longitudinal axis,
wherein the method comprises a peripheral surface grinding step of grinding a peripheral surface of the single crystal blank at least partially along the longitudinal axis,
wherein the peripheral surface of the single crystal blank is ground up to a first distance to the longitudinal axis at least partially along a portion of the longitudinal axis excluding the seed crystal, wherein the first distance is less than an extension of the seed crystal to the longitudinal axis.

2. The method according to claim 1,
wherein the peripheral surface of the single crystal blank is ground at least partially along the longitudinal axis up to a second distance to the longitudinal axis, the second distance being greater than or substantially equal to an extension of the seed crystal to the longitudinal axis.

3. The method according to claim 2,
wherein the peripheral surface of the single crystal blank is ground at least along a seed portion of the longitudinal axis up to the second distance to the longitudinal axis, the seed portion including the seed crystal, in particular the entire seed crystal.

4. The method according to claim 1,
wherein the method further comprises a wafer producing step of producing a wafers from the single crystal blank, the wafer having a predetermined thickness along the longitudinal axis,
wherein the wafer producing step preferably comprises a sub-step of focusing a laser beam inside the single crystal blank.

5. The method according to claim 1, wherein the method further comprises the steps of:
a seed crystal providing step of providing the seed crystal for crystal growth; and
a crystal growing step of growing a single crystal on a surface of the seed crystal for forming the single crystal blank.

6. The method according to claim 1, wherein the method further comprises the step of:
a seed crystal processing step 4 of processing the seed crystal, the seed crystal processing step preferably including grinding and/or polishing of the seed crystal.

7. The method according to claim 1,
wherein the single crystal blank is processed for forming an ingot or a wafer, wherein the wafer is particularly formed using a laser beam, a blade and/or a wire saw.

8. An apparatus for processing a single crystal blank,
the single crystal blank having a first end a second end and a longitudinal axis extending between said first end and said second end, wherein the single crystal blank comprises a seed crystal and a single crystal, the seed crystal extending at least partially along the longitudinal axis,
wherein the apparatus comprises a peripheral surface grinding means configured to grind a peripheral surface of the single crystal blank at least partially along the longitudinal axis,
wherein the peripheral surface grinding means is configured to grind the peripheral surface of the single crystal blank up to a first distance to the longitudinal axis at least partially along a portion of the longitudinal axis excluding the seed crystal, wherein the first distance is preferably less than an extension of the seed crystal the longitudinal axis.

9. The apparatus according to claim 8,
wherein the peripheral surface grinding means is further configured to grind the peripheral surface of the single crystal blank at least partially along the longitudinal axis up to a second distance to the longitudinal axis, the second distance being greater than or substantially equal to an extension of the seed crystal to the longitudinal axis.

10. The apparatus according to claim 9,
wherein the peripheral surface grinding means is further configured to grind the peripheral surface of the single crystal blank at least along a seed portion of the longitudinal axis up to the second distance to the longitudinal the seed portion including the seed crystal, in particular the entire seed crystal.
